(19) United States
(12) Patent Application Publication
(10) Pub. No.: US 2023/0403872 A1
(43) Pub. Date: Dec. 14, 2023

(54) LIGHT-EMITTING DEVICE, DISPLAY PANEL AND DISPLAY APPARATUS

(71) Applicant: BOE Technology Group Co., Ltd., Beijing (CN)

(72) Inventors: Lihui MA, Beijing (CN); Meng SUN, Beijing (CN)

(21) Appl. No.: 18/033,494

(22) PCT Filed: Nov. 20, 2020
(86) PCT No.: PCT/CN2020/130661

§ 371 Date: Apr. 24, 2023

(51) Int. Cl. H10K 50/11; H10K 50/18; H10K 50/15; H10K 85/60

(52) U.S. Cl. CPC H10K 50/11; H10K 50/181; H10K 50/15; H10K 85/6572

(57) ABSTRACT

A light-emitting device, a display panel and a display apparatus are disclosed. The light-emitting device includes an anode and a cathode arranged oppositely, and a light-emitting function layer located between the anode and the cathode; the light-emitting function layer includes a light-emitting layer, a first auxiliary function layer located between the light-emitting layer and the anode, a second auxiliary function layer located between the light-emitting layer and the cathode, and at least one co-doped layer; and a difference in material physical properties between two film layers adjacent to the co-doped layer is greater than a set value, and the co-doped layer includes a material formed by mixing materials of the two adjacent film layers.

### FIELD

The present disclosure relates to the technical field of display, and particularly to a light-emitting device, a display panel and a display apparatus.

### BACKGROUND

Organic electroluminescence devices are widely used in mobile phones, tablets and other fields due to their advantages of self-luminescence, full curing, flexibility, wide color gamut and so on. The energy level potential barrier between interfaces in the organic electroluminescence device is too large, resulting in charge injection difficulties and influence on a brightening voltage and a low gray level characteristic of the device. The large energy level potential barrier also leads to the accumulation of charges on the interfaces, which affects the efficiency and life of the device.

### SUMMARY

An embodiment of the present disclosure provides a light-emitting device, including an anode and a cathode arranged oppositely, and a light-emitting function layer located between the anode and the cathode;
the light-emitting function layer including a light-emitting layer, a first auxiliary function layer located between the light-emitting layer and the anode, a second auxiliary function layer located between the light-emitting layer and the cathode, and at least one co-doped layer; and
a difference in material physical properties between two film layers adjacent to the co-doped layer being greater than a set value, and the co-doped layer including a material formed by mixing materials of the two adjacent film layers.

In a possible implementation, in the light-emitting device provided by an embodiment of the present disclosure, an energy level potential barrier between the two film layers adjacent to the co-doped layer is greater than or equal to 0.2 eV.

In a possible implementation, in the light-emitting device provided by an embodiment of the present disclosure, the first auxiliary function layer includes an electron blocking layer;
the light-emitting layer includes a blue organic light-emitting material, and an energy level potential barrier between the electron blocking layer and the light-emitting layer is greater than 0.2 eV; and the co-doped layer includes a first co-doped layer located between the electron blocking layer and the light-emitting layer.

In a possible implementation, in the light-emitting device provided by an embodiment of the present disclosure, an HOMO value of the blue organic light-emitting material is 5.9 eV, and an HOMO value of the electron blocking layer is 5.5 eV.

In a possible implementation, in the light-emitting device provided by an embodiment of the present disclosure, the first auxiliary function layer includes a hole transport layer;
the light-emitting layer includes a blue organic light-emitting material, and an energy level potential barrier between the hole transport layer and the light-emitting layer is greater than 0.2 eV; and the co-doped layer includes a second co-doped layer located between the hole transport layer and the light-emitting layer.

In a possible implementation, in the light-emitting device provided by an embodiment of the present disclosure, an HOMO value of the blue organic light-emitting material is 5.9 eV, and an HOMO value of the hole transport layer is 5.4 eV.

In a possible implementation, in the light-emitting device provided by an embodiment of the present disclosure, the second auxiliary function layer includes an electron transport layer and a hole blocking layer;
an energy level potential barrier between the electron transport layer and the hole blocking layer is greater than 0.2 eV; and
the co-doped layer includes a third co-doped layer located between the electron transport layer and the hole blocking layer.

In a possible implementation, in the light-emitting device provided by an embodiment of the present disclosure, an LUMO value of the electron transport layer is 3.0 eV, and an LUMO value of the hole blocking layer is 2.6 eV.

In a possible implementation, in the light-emitting device provided by an embodiment of the present disclosure, the second auxiliary function layer includes a hole blocking layer;
the light-emitting layer includes a green organic light-emitting material, and an energy level potential barrier between the hole blocking layer and the light-emitting layer is greater than 0.2 eV; and the co-doped layer includes a fourth co-doped layer located between the hole blocking layer and the light-emitting layer.
In a possible implementation, in the light-emitting device provided by an embodiment of the present disclosure, an LUMO value of the hole blocking layer is 2.6 eV, and an LUMO value of the green organic light-emitting material is 2.3 eV.

In a possible implementation, in the light-emitting device provided by an embodiment of the present disclosure, a difference in a carrier mobility between the two film layers adjacent to the co-doped layer is greater than an order of magnitude.

In a possible implementation, in the light-emitting device provided by an embodiment of the present disclosure, the first auxiliary function layer includes an electron blocking layer;
the light-emitting layer includes a green organic light-emitting material, and a difference in a hole mobility between the electron blocking layer and the light-emitting layer is at least an order of magnitude; and the co-doped layer includes a fifth co-doped layer located between the electron blocking layer and the light-emitting layer.

In a possible implementation, in the light-emitting device provided by an embodiment of the present disclosure, a hole mobility of the electron blocking layer is 2.2 E-04 cm²/Vs, and a hole mobility of the green organic light-emitting material is 2.8 E-07 cm²/Vs.

In a possible implementation, in the light-emitting device provided by an embodiment of the present disclosure, the first auxiliary function layer includes a hole transport layer;
the light-emitting layer includes a green organic light-emitting material, and a difference in a hole mobility between the hole transport layer and the light-emitting layer is at least an order of magnitude; and
the co-doped layer includes a sixth co-doped layer located between the hole transport layer and the light-emitting layer.

In a possible implementation, in the light-emitting device provided by an embodiment of the present disclosure, a hole mobility of the hole transport layer is 2.2 E-04 cm²/Vs, and a hole mobility of the green organic light-emitting material is 2.8 E-07 cm²/Vs.

In a possible implementation, in the light-emitting device provided by an embodiment of the present disclosure, a thickness of the co-doped layer is 3 nm to 10 nm.

In a possible implementation, in the light-emitting device provided by an embodiment of the present disclosure, a thickness of the co-doped layer is 5 nm to 8 nm.

In a possible implementation, in the light-emitting device provided by an embodiment of the present disclosure, a mass ratio of materials of the two adjacent film layers in the co-doped layer is 1:9 to 9:1.

In a possible implementation, in the light-emitting device provided by an embodiment of the present disclosure, a mass ratio of the materials of the two adjacent film layers in the co-doped layer is 1:1.

In a possible implementation, in the light-emitting device provided by an embodiment of the present disclosure, a light-emitting host material in the blue organic light-emitting material is TCTA or Bphen, and a guest material in the blue organic light-emitting material is an aromatic or aniline luminophore; and
a material of the hole transport layer is a triphenylamine, butadiene or styryl triphenylamine compound, and a material of the electron blocking layer is an aniline or carbazole compound.

In a possible implementation, in the light-emitting device provided by an embodiment of the present disclosure, a material of the hole blocking layer is BCP, and a material of the electron transport layer is PBD or NCB.

In another aspect, an embodiment of the present disclosure further provides a display panel, including the plurality of light-emitting devices provided by an embodiment of the present disclosure.

In a possible implementation, in the display panel provided by an embodiment of the present disclosure, the light-emitting devices include a blue light-emitting device, a green light-emitting device and a red light-emitting device; and
the blue light-emitting device includes a first co-doped layer, and the green light-emitting device includes a fifth co-doped layer.

In a possible implementation, in the display panel provided by an embodiment of the present disclosure, the red light-emitting device includes a seventh co-doped layer located between an electron blocking layer and the light-emitting layer.

In another aspect, an embodiment of the present disclosure further provides a display apparatus, including the display panel provided by an embodiment of the present disclosure.

### BRIEF DESCRIPTION OF DRAWINGS

FIG. 1 is a schematic diagram of energy level distribution of film layers in a blue organic electroluminescence device.

FIG. 2 is a schematic diagram of energy level distribution of film layers in a green organic electroluminescence device.

FIG. 3 is a schematic diagram of energy level distribution of film layers in a red organic electroluminescence device.

FIG. 4 is a schematic structural diagram of a light-emitting device provided by an embodiment of the present disclosure.

FIG. 5 is another schematic structural diagram of a light-emitting device provided by an embodiment of the present disclosure.

FIG. 6 is another schematic structural diagram of a light-emitting device provided by an embodiment of the present disclosure.

FIG. 7 is another schematic structural diagram of a light-emitting device provided by an embodiment of the present disclosure.

FIG. 8 is another schematic structural diagram of a light-emitting device provided by an embodiment of the present disclosure.

FIG. 9 is another schematic structural diagram of a light-emitting device provided by an embodiment of the present disclosure.

FIG. 10 is another schematic structural diagram of a light-emitting device provided by an embodiment of the present disclosure.

FIG. 11 is another schematic structural diagram of a light-emitting device provided by an embodiment of the present disclosure.

FIG. 12 is a Nyquist impedance spectroscopy of a light-emitting device provided by an embodiment of the present disclosure.

FIG. 13 is another Nyquist impedance spectroscopy of a light-emitting device provided by an embodiment of the present disclosure.

FIG. 14 is a schematic structural diagram of a display panel provided by an embodiment of the present disclosure.

### DETAILED DESCRIPTION OF EMBODIMENTS

To make objectives, technical solutions and advantages of embodiments of the present disclosure clearer, the present disclosure will be further described in detail below in conjunction with the accompanying drawings. Obviously, the described embodiments are one part of embodiments of the present disclosure, not all of them. On the basis of embodiments in the present disclosure, all other embodiments acquired by those ordinarily skilled in the art without creative labor fall within the scope of protection of the present disclosure.

Shapes and sizes of the parts in the accompanying drawings do not reflect the true scale and are intended only to illustrate the contents of the present disclosure.

An organic electroluminescence device generally includes a cathode, an anode and an organic material clamped between the cathode and the anode. According to different functions of the organic material, the organic material may be roughly divided into a hole injection material, a hole transport material, an electron injection material, an electron transport material, a light-emitting material, a hole blocking material, an electron blocking material, and so on. The anode is generally made of indium tin oxide (ITO) with a higher work function, and the work function is about 4.8 ev. A highest occupied molecular orbital (HOMO) of a blue light-emitting host material is about 6.0 ev, injection of holes into a blue light-emitting layer from the anode needs to overcome a 1.2 ev energy level potential barrier, and an energy level potential barrier between interfaces may be weakened by evaporating different auxiliary function layers with ladder-changing HOMO energy levels, that is, under the effect of an external electric field, the holes are injected from the ITO and reach the light-emitting layer via hole injection layer, hole transport layer and electron blocking layer materials. A cathode material generally adopts relatively active aluminum (Al) or magnesium (Mg) or silver (Ag) alloys, electrons are injected from the cathode under the effect of the external electric field, and reach the light-emitting layer via electron injection layer, electron transport layer and hole blocking layer materials. In the light-emitting layer, the electrons and the holes meet to form excitons, and the excitons are compounded to emit light.

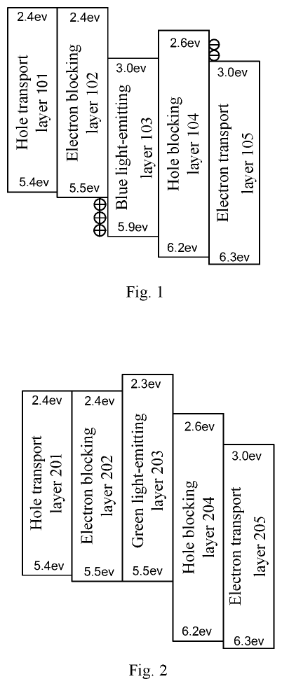

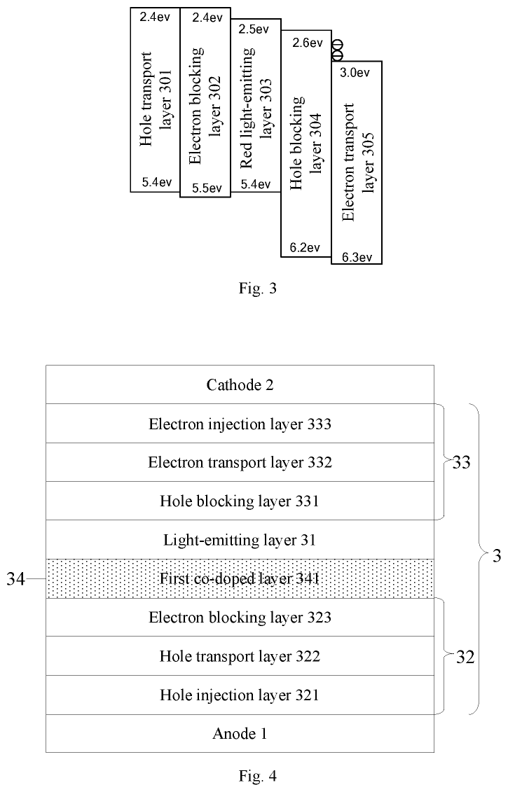

Although auxiliary material layer materials with different energy levels are arranged between the cathode and the anode to serve an injection layer, a transport layer and a barrier layer, too large energy level potential barriers in some interfaces still exist. FIG. 1 shows energy level data of film layers commonly used in a blue organic electroluminescence device, which may be seen that a 0.4 ev energy level potential barrier exists between materials of an electron blocking layer 102 and a blue light-emitting layer 103, resulting in hole injection difficulty, and a 0.4 ev energy level potential barrier also exists between an electron transport layer 105 and a hole blocking layer 104, resulting in electron injection difficulties. Interfaces with greater energy level potential barriers also exist in a green organic electroluminescence device shown in FIG. 2 and a red organic electroluminescence device shown in FIG. 3. The greater energy level potential barriers lead to charge injection difficulties and influences on a brightening voltage and a low gray scale characteristic of the devices, and the large energy level potential barriers lead to accumulation of charges on the interfaces and influences on the service life of the devices.

In addition, as shown in FIG. 2 and FIG. 3, although the energy level potential barriers of the interfaces in the green organic electroluminescence device and the red organic electroluminescence device are generally smaller than the energy level potential barriers of the interfaces of a blue organic electroluminescence device, a greater difference exists in a mobility between a material of an electron blocking layer 202 and a material of a green light-emitting layer 203 in the green organic electroluminescence device, as shown in table 1. A hole mobility of the green light-emitting layer 203 is far lower than a hole mobility of the electron blocking layer 202. The greater difference of the mobility between adjacent materials may also lead to accumulation of a large number of charges on the interfaces and the influences on the performance of the device.

TABLE 1

| | | Green light-emitting |
|---|---|---|
| | Electron blocking layer | layer |
| Hole mobility (cm²/Vs) | 2.2E−04 | 2.8E−07 |

On this basis, embodiments of the present disclosure provide a light-emitting device, a display panel and a display apparatus, for interfaces with greater interface energy level potential barriers or greater mobility differences, the difference of physical properties on the interfaces may be weakened, the injection capability of carriers is improved, and accumulations of interface charges are obviously reduced by mutually doping materials of the adjacent interfaces in the case of not introducing other new organic materials.

An embodiment of the present disclosure provides a light-emitting device, as shown in FIG. 4 to FIG. 11, including an anode 1 and a cathode 2 arranged oppositely, and a light-emitting function layer 3 located between the anode 1 and the cathode 2;
the light-emitting function layer 3 includes a light-emitting layer 31, a first auxiliary function layer 32 located between the light-emitting layer 31 and the anode 1, a second auxiliary function layer 33 located between the light-emitting layer 31 and the cathode 2, and at least one co-doped layer 34; and
a difference in material physical properties between two film layers adjacent to the co-doped layer 34 is greater than a set value, and the co-doped layer 34 includes a material formed by mixing materials of the two adjacent film layers.

In the light-emitting device provided by an embodiment of the present disclosure, the co-doped layer is added between interfaces with the difference in the material physical properties being greater than a set value, which may obviously reduce the difference in the physical properties of the adjacent interfaces, enhance the injection capability of charges, and obviously reduce accumulation of the charges on the interfaces, thereby weakening the difference in the interfaces in the light-emitting device and improving the performance of the device. Compared with a traditional method that an auxiliary function layer is added in a light-emitting device to weaken the difference in physical properties on the interfaces, a new organic material does not need to be introduced, the requirement of the traditional method of adding the auxiliary function layer for the property (such as the energy level) of the newly-introduced organic material is higher, the property (such as the energy level) needs to be located between the properties (such as energy levels) of two interface materials, and therefore particular material design is needed. In the light-emitting device provided by an embodiment of the present disclosure, materials of adjacent interfaces with greater difference in the physical properties are mutually doped to form the co-doped layer, which ensures that a good contact interface is formed between the co-doped layer and adjacent film layers and injection and transport of charges are more easily performed.

In the light-emitting device provided by an embodiment of the present disclosure, the light-emitting layer 31 may be an organic light-emitting material, and may also be a quantum dot light-emitting material, which is not limited here. When the light-emitting layer 31 adopts the organic light-emitting material, the light-emitting device may be called an organic electroluminescence device, and when the light-emitting layer 32 adopts the quantum dot light-emitting material, the light-emitting device may be called a quantum dot light-emitting device. The organic electroluminescence device is taken as an example below to illustrate specific film layer positions and properties of the co-doped layer 34 in the above light-emitting device provided in the present disclosure.

Optionally, in the light-emitting device provided by an embodiment of the present disclosure, the difference of the material physical properties between two film layers being greater than the set value may also be specified as: an energy level potential barrier between two film layers adjacent to the co-doped layer 34 is greater than or equal to 0.2 ev. When the interface energy level potential barrier between the adjacent film layers is greater than 0.2 eV, it leads to charge injection difficulties and influences on a brightening voltage and a low gray scale characteristic of the device, and the large energy level potential barrier also leads to accumulation of charges on the interfaces and influences on the service life of the device. Therefore, for the interfaces with the interface energy level potential barriers being greater than 0.2 eV, the energy level potential barriers on the interfaces may be weakened, the injection capability of carriers is improved, and accumulations of charges on the interfaces are obviously reduced by mutually doping materials of the adjacent interfaces in the case of not introducing other new organic materials. Moreover, the energy level of the co-doped layer 34 added on the interface with the greater energy level potential barrier is closer to the energy level of the adjacent low energy level film layer.

Or, optionally, in the light-emitting device provided by an embodiment of the present disclosure, the difference of the material physical properties between two film layers being greater than the set value may also be specified as: a difference in a carrier mobility between the two film layers adjacent to the co-doped layer 34 is greater than an order of magnitude. For example, table 1 shows that the hole mobility of the green light-emitting layer is far lower than the hole mobility of the electron blocking layer, and when the difference in the carrier mobility between the two film layers adjacent to the co-doped layer is greater than an order of magnitude, a large number of charges are accumulated on the interface, which affects the service life of the device. Moreover, the carrier mobility of the co-doped layer 34 added on the interface with the greater difference in the carrier mobility is closer to the carrier mobility of the adjacent low carrier mobility film layer.

In the light-emitting device provided by an embodiment of the present disclosure, the first auxiliary function layer 32 may include one or a combination of a hole injection layer 321, a hole transport layer 322 or an electron blocking layer 323; the second auxiliary function layer 33 may include one or a combination of an electron injection layer 333, an electron transport layer 332 or a hole blocking layer 331; and the light-emitting layer 31 may include a blue organic light-emitting material, a green organic light-emitting material, a red organic light-emitting material and so on. According to different selected materials of the light-emitting layer 31, and different film layer structures of the first auxiliary function layer 32 and the second auxiliary function layer 33, the co-doped layer 34 may be set on different film layer positions according to the difference in the energy level potential barriers between the interfaces and the difference in the mobility between the interfaces.

For example, optionally, in the light-emitting device provided by an embodiment of the present disclosure, as shown in FIG. 4, when the first auxiliary function layer 32 includes an electron blocking layer 323, and the light-emitting layer 31 includes the blue organic light-emitting material, a light-emitting host material in the blue organic light-emitting material is generally TCTA or Bphen, a guest material in the blue organic light-emitting material is generally an aromatic or aniline luminophore, and a material of the electron blocking layer 323 is generally an aniline or carbazole compound. Refer to energy level data shown in FIG. 1, an HOMO value of the blue organic light-emitting material is 5.9 eV, an HOMO value of the electron blocking layer 323 is 5.5 eV, an energy level potential barrier between the electron blocking layer 323 and the light-emitting layer 31 is 0.4 eV and greater than 0.2 eV, consequently, hole injection is difficult, the co-doped layer 34 needs to be set, therefore, the co-doped layer 34 may include a first co-doped layer 341 located between the electron blocking layer 323 and the light-emitting layer 31, and the first co-doped layer 341 may weaken the energy level potential barrier between the interfaces, and improve the hole injection capability. It should be noted that the HOMO value and the LUMO value mentioned in the present disclosure refer to numerical values of energy levels, and do not include positive and negative polarity of the energy levels.

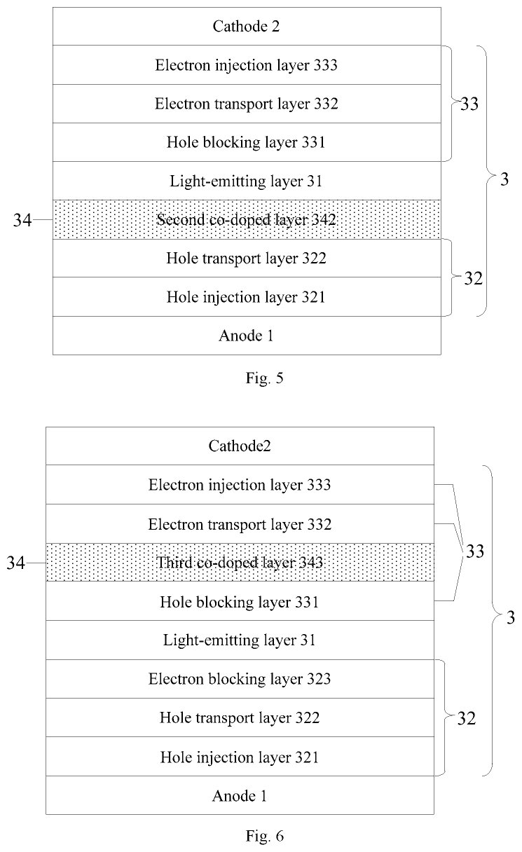

For example, optionally, in the light-emitting device provided by an embodiment of the present disclosure, as shown in FIG. 5, when the first auxiliary function layer 32 includes a hole transport layer 322, and the light-emitting layer 31 includes the blue organic light-emitting material, that is, when no electron barrier layer 323 is set between the hole transport layer 322 and the light-emitting layer 31, the light-emitting host material in the blue organic light-emitting material is generally TCTA or Bphen, the guest material in the blue organic light-emitting material is generally an aromatic or aniline luminophore, and a material of the hole transport layer 322 is generally a triphenylamine, butadiene or styryl triphenylamine compound. Refer to energy level data shown in FIG. 1, the HOMO value of the blue organic light-emitting material is 5.9 eV, an HOMO value of the hole transport layer 322 is 5.4 eV, an energy level potential barrier between the hole transport layer 322 and the light-emitting layer 31 is 0.5 eV and greater than 0.2 eV, consequently, hole injection is difficult, the co-doped layer 34 needs to be set, therefore, the co-doped layer 34 may include a second co-doped layer 342 located between the hole transport layer 322 and the light-emitting layer 31, and the second co-doped layer 342 may weaken the energy level potential barrier between the interfaces, and improve the hole injection capability.

For example, optionally, in the light-emitting device provided by an embodiment of the present disclosure, as shown in FIG. 6, when the second auxiliary function layer 33 includes an electron transport layer 332 and a hole blocking layer 331, a material of the hole blocking layer 331 is generally BCP, and a material of the electron transport layer 332 is generally PBD or NCB. Refer to energy level data shown in FIG. 1 to FIG. 3, an LUMO value of the electron transport layer 332 is 3.0 eV, an LUMO value of the hole blocking layer 331 is 2.6 eV, an energy level potential barrier between the electron transport layer 332 and the hole blocking layer 331 is 0.4 eV and greater than 0.2 eV, consequently, electron injection is difficult, the co-doped layer 34 needs to be set, therefore, the co-doped layer 34 may include a third co-doped layer 343 located between the electron transport layer 332 and the hole blocking layer 331, and the third co-doped layer 343 may weaken the energy level potential barrier between the interfaces, and improve the electron injection capability.

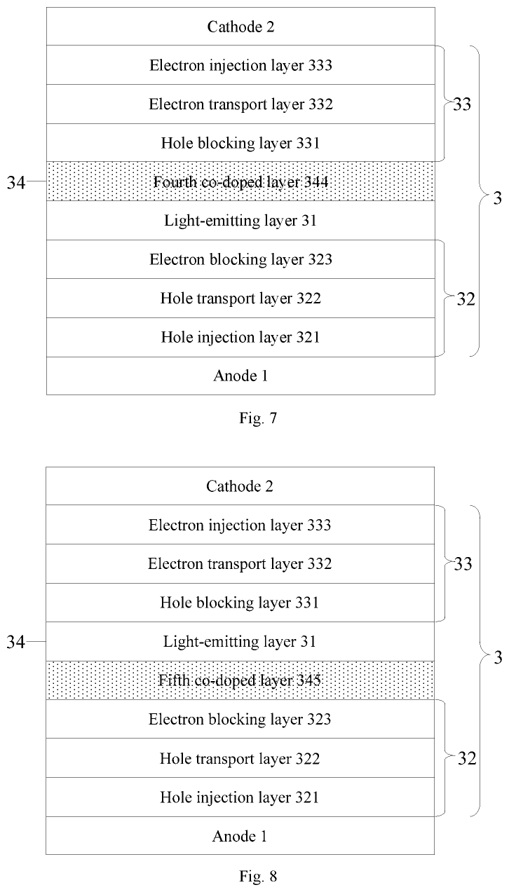

For example, optionally, in the light-emitting device provided by an embodiment of the present disclosure, as shown in FIG. 7, when the second auxiliary function layer 33 includes a hole blocking layer 331, and the light-emitting layer 31 includes a green organic light-emitting layer, refer to energy level data shown in FIG. 2, an LUMO value of the hole blocking layer 331 is 2.6 eV, an LUMO value of the green organic light-emitting layer is 2.3 eV, an energy level potential barrier between the hole blocking layer 331 and the light-emitting layer 31 is 0.3 eV and greater than 0.2 eV, consequently, electron injection is difficult, the co-doped layer 34 needs to be set, therefore, the co-doped layer 34 may include a fourth co-doped layer 344 located between the hole blocking layer 331 and the light-emitting layer 31, and the fourth co-doped layer 344 may weaken the energy level potential barrier between the interfaces, and improve the electron injection capability.

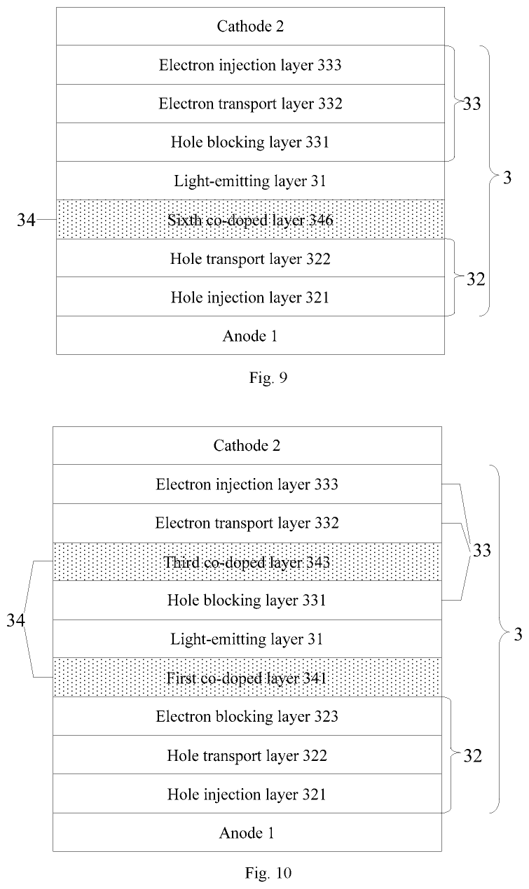

For example, optionally, in the light-emitting device provided by an embodiment of the present disclosure, as shown in FIG. 8, when the first auxiliary function layer 32 includes an electron blocking layer 323, and the light-emitting layer 31 includes a green organic light-emitting material, referring to hole mobility data shown in table 1, a hole mobility of the electron blocking layer 323 is 2.2 E-04 cm²/Vs, a hole mobility of the green organic light-emitting material is 2.8 E-07 cm²/Vs, a difference in a hole mobility between the electron blocking layer 323 and the light-emitting layer 31 is at least one order of magnitude, resulting in accumulations of a large number of charges on interfaces, a co-doped layer 34 needs to be set, the co-doped layer 34 may include a fifth co-doped layer 345 located between the electron blocking layer 323 and the light-emitting layer 31, and the fifth co-doped layer 345 may weaken the hole mobility difference between the interfaces, and improve the hole injection capability. For example, optionally, in the light-emitting device provided by an embodiment of the present disclosure, as shown in FIG. 9, when the first auxiliary function layer 32 includes an hole transport layer 322, and the light-emitting layer 31 includes a green organic light-emitting material, that is, no electron blocking layer 323 is set between the hole transport layer 322 and the light-emitting layer 31, a hole mobility of the hole transport layer 322 is 2.2 E-04 cm²/Vs, a hole mobility of the green organic light-emitting material is 2.8 E-07 cm²/Vs, a difference in a hole mobility between the hole transport layer 322 and the light-emitting layer 31 is at least one order of magnitude, resulting in accumulations of a large number of charges on interfaces, a co-doped layer 34 needs to be set, the co-doped layer 34 may include a sixth co-doped layer 346 located between the hole transport layer 322 and the light-emitting layer 31, and the sixth co-doped layer 346 may weaken the hole mobility difference between the interfaces and improve the hole injection capability.

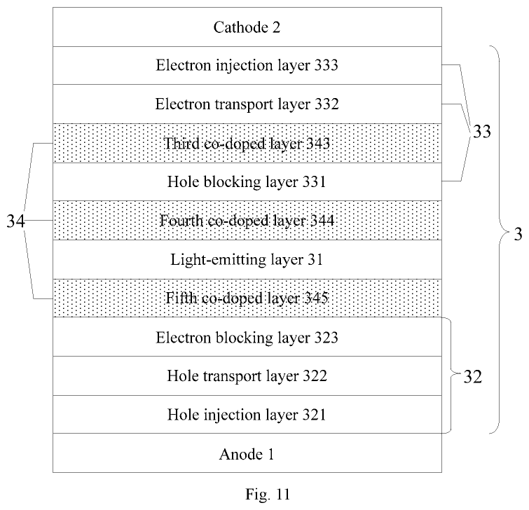

It should be noted that for facilitating descriptions, FIG. 4 to FIG. 9 only illustrate the case of setting one co-doped layer 34 in the light-emitting device. In the light-emitting device provided by an embodiment of the present disclosure, a plurality of co-doped layers 34 may be set in one light-emitting device according to the difference in the energy level potential barrier between the interfaces and the difference in the mobility between the interfaces. For example, in the blue light-emitting device shown in FIG. 10, the first co-doped layer 341 and the third co-doped layer 343 may be set at the same time with reference to the energy level data shown in FIG. 1. For another example, the third co-doped layer 343, the fourth co-doped layer 344 and the fifth co-doped layer 345 may be set at the same time in the green light-emitting device shown in FIG. 11 with reference to energy level data shown in FIG. 2.

Optionally, in the light-emitting device provided by an embodiment of the present disclosure, the co-doped layer 34 is made of two materials by a common evaporating, a thickness of the co-doped layer 34 is generally controlled to be 3 nm to 10 nm, the thickness of the co-doped layer 34 is optionally controlled to be 5 nm to 8 nm, a mass ratio of materials of two adjacent film layers in the co-doped layer 34 is generally controlled to be 1:9-9:1, and the mass ratio is optionally controlled to be 1:1.

During manufacturing of the light-emitting device provided by an embodiment of the present disclosure, an upright structure may be adopted, that is, a manufacturing sequence of manufacturing the anode and then manufacturing the light-emitting function layer and the cathode in sequence on a substrate. An inverted structure may also be adopted, that is a manufacturing sequence of manufacturing the cathode and then manufacturing the light-emitting function layer and the anode in sequence on the substrate, which is not detailed here. A structure shown in FIG. 4 is taken as an example below, a manufacturing process of the light-emitting device provided by an embodiment of the present disclosure is introduced, and a detailed process is as follows.

In a first step, cleaning of an anode ITO base substrate is as follows.
1. Ultrasonic cleaning using an isopropyl alcohol solution is performed, and ultrasonic cleaning is performed for 10 minutes.
2. Ultrasonic cleaning using deionized water is performed, and ultrasonic cleaning is performed for 10 minutes.
3. Drying of the substrate is performed, a set temperature is 100° C., and drying is performed for 1 hour in a nitrogen environment.
4. After drying, the substrate is irradiated under an ultraviolet lamp for 10 minutes.

In a second step, vacuum evaporation of materials of light-emitting function layers is performed, high-temperature evaporation is performed on the materials of the light-emitting function layers under a vacuum degree of 10⁻⁵-10⁻⁷ Pascal, and an evaporation sequence is as follows.
1. Preparation of a hole injection layer: a hole doping material and a hole transport material are co-evaporated, an evaporation thickness is 3 nm to 20 nm, for example, the evaporation thickness is 10 nm, a doping mass ratio of the hole doping material in the hole injection layer is controlled to be 1% to 5%, the hole doping material is a radialene compound, a preferred material is TF-TCNQ, PEDOT-PSS, etc., and a structural formula is as follows:

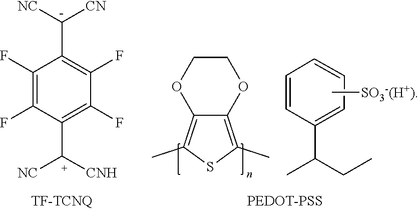

2. Preparation of a hole transport layer and an electron blocking layer: vacuum evaporation of the hole transport layer and the electron blocking layer is performed, an evaporation thickness of the hole transport layer is 50 nm to 150 nm, for example, the evaporation thickness is 80 nm, the material of the hole transport layer is triphenylamines, butadienes, styryl-triphenylamines, etc., TPD is preferred; and an evaporation thickness of the electron blocking layer is 5 nm to 15 nm, for example, the evaporation thickness is 5 nm, the material of the electron blocking layer is mainly the aniline and carbazole compound, the preferred material is TAPC, TPD, etc., and a structural formula is as follows:

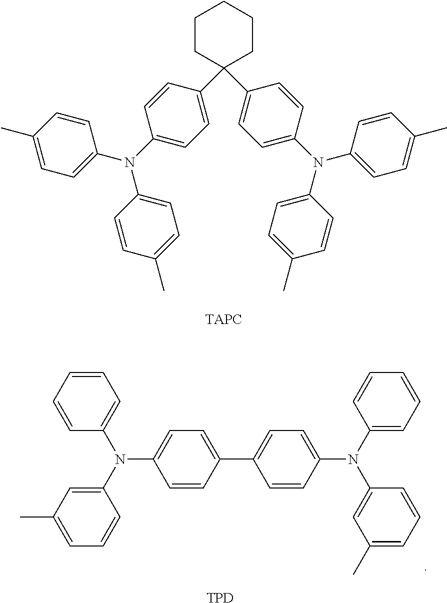

3. Preparation of a first co-doped layer: a material of the hole transport layer and a light-emitting host material are doped and co-evaporated, a mutual doping ratio is 1:1, and a thickness of the film layer is 5 nm.
4. Preparation of a blue light-emitting layer: the light-emitting layer is prepared by doping the light-emitting host material and a guest material, a doping ratio of the guest material is 1% to 20%, a thickness of the light-emitting layer is 10 nm to 50 nm, for example, the evaporation thickness is 20 nm, the light-emitting host material is TCTA or Bphen, the guest material is mostly an aromatic or aniline luminophore and preferred as perylene, AND, and a structural formula is as follows:

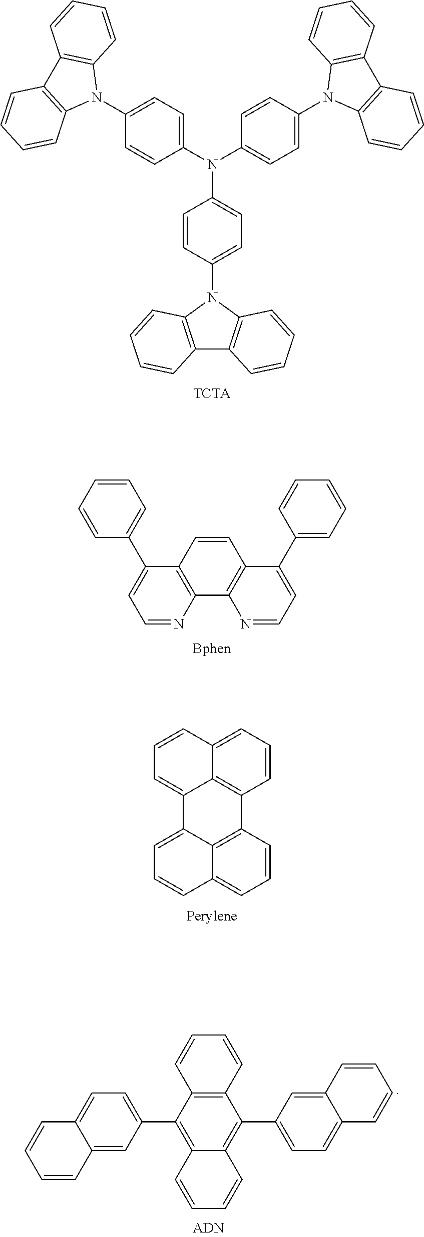

5. Preparation of an electron transport layer and hole blocking layer material: the material of the hole blocking layer is BCP, an evaporation thickness is about 5 nm, the material of the electron transport layer is prepared by co-evaporating a planar aromatic compound and Alq, the material of the electron transport layer is PBD or NCB, a doping ratio is 10% to 90%, an evaporation thickness is about 30 nm, and a chemical structural formula is as follows:

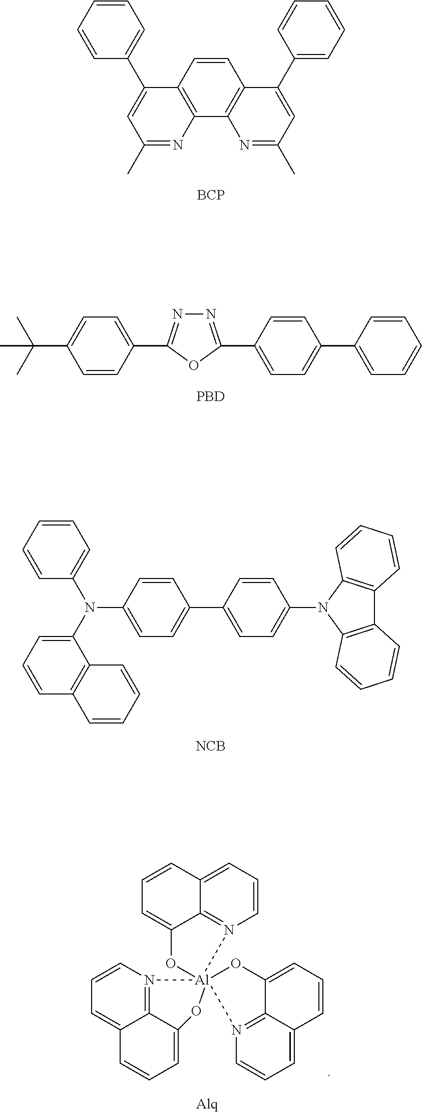

6. Preparation of an electron injection layer: the material of the electron injection layer is ytterbium metal and lithium fluoride, and a thickness is 0.5 nm to 2 nm, for example, the thickness is 1 nm.
7. Preparation of a cathode: the material of the cathode is aluminum (Al) or magnesium (Mg) or silver (Ag) for co-evaporating for the cathode, a thickness is 80 nm to 150 nm, and an alloying ratio of the co-evaporated cathode is 2:8 to 1:9.
8. Device encapsulation: the evaporated device is encapsulated, ultraviolet encapsulation may be adopted. Firstly, an encapsulation glue sensitive to ultraviolet rays is glued to the periphery of a glass cover plate, then, the base substrate with the evaporated device is attached to the glass cover plate, and then, an ultraviolet lamp is configured to irradiate the encapsulation glue for 15 min for solidifying to finish encapsulation.

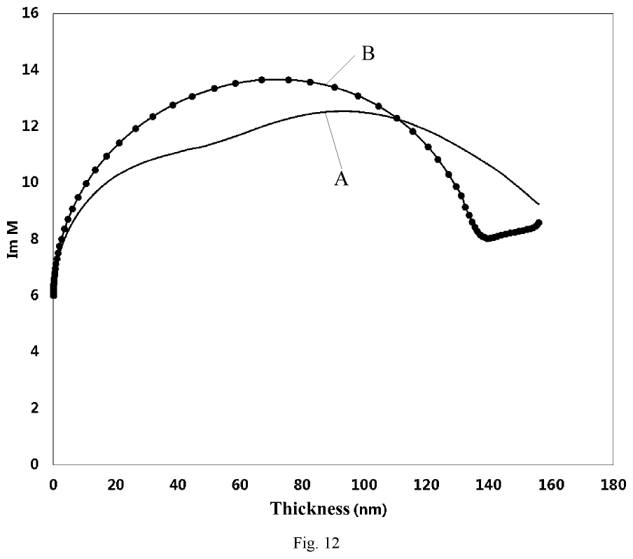

An impedance spectroscopy test is performed on the light-emitting device without the first co-doped layer 341 and the light-emitting device manufactured with the first co-doped layer 341, a test frequency is set to 1 Hertz to 1 million Hertz, a direct current voltage is 3.0 volts, and a voltage of an alternating-current signal is 100 millivolts. A test result is as shown in FIG. 12, a Nyquist impedance spectroscopy B of the light-emitting device manufactured with the first co-doped layer 341 is a standard semi-circle, the light-emitting device may be equivalent to an RC circuit, and an obvious interface does not exist between interfaces in the light-emitting device. A Nyquist impedance spectroscopy A of the light-emitting device without the first co-doped layer 341 is composed of two semicircles, which proves that an obvious interface exists in the light-emitting device.

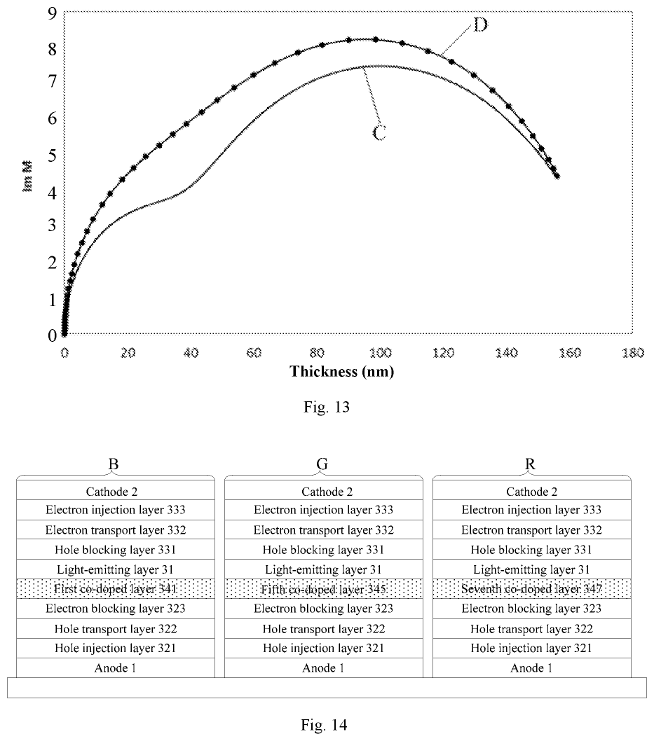

Referring to the manufacturing method, the blue light-emitting device including the third co-doped layer 343 shown in FIG. 6 is manufactured, the mutually-doped ratio of the material of the electron transport layer to the material of the hole blocking layer in the third co-doped layer 343 is 1:1, and a thickness of the third co-doped layer 343 is 5 nm. The same condition is adopted for performing an impedance spectroscopy test on the light-emitting device without the third co-doped layer 343 and the light-emitting device manufactured with the third co-doped layer 343, a test result is as shown in FIG. 13. It may also be seen that a Nyquist impedance spectroscopy D of the light-emitting device manufactured with the third co-doped layer 343 is an approximate semi-circle, the light-emitting device may be equivalent to an RC circuit, and the light-emitting device obviously weakens the potential barrier of between interfaces of the light-emitting device. A Nyquist impedance spectroscopy C of the light-emitting device without the third co-doped layer 343 is composed of two semicircles, which proves that an obvious interface exists in the light-emitting device.

Referring to the manufacturing method, the green light-emitting device including the fifth co-doped layer 345 shown in FIG. 8 is manufactured, the mutually-doped ratio of the light-emitting host material to the material of the hole transport layer in the fifth co-doped layer 345 is 1:1, and a thickness of the fifth co-doped layer 345 is 8 nm. A test is performed for current-voltage-brightness information of the green light-emitting device including the fifth co-doped layer 345 and the green light-emitting device without the fifth co-doped layer 345 under a fixed current, as shown in table 2, the electron blocking layer and the green light-emitting layer material with the greater difference in mobility are mutually doped, accumulation of holes on the interface is reduced, and the efficiency of the light-emitting device is improved by more than 3%.

TABLE 2

| | | Current | Chromaticity | Chromaticity |
|---|---|---|---|---|
| | Voltage | efficiency | coordinate | coordinate |
| | (V) | (cd/A) | (X) | (Y) |
| Green light-emitting | 100% | 100% | 0.256 | 0.721 |
| device without fifth | | | | |
| co-doped layer | | | | |
| Green light-emitting | 106% | 103% | 0.248 | 0.717 |
| device with fifth | | | | |
| co-doped layer | | | | |

Based on the same inventive conception, an embodiment of the present disclosure further provides a display panel, including a plurality of light-emitting devices provided by an embodiment of the present disclosure. As shown in FIG. 14, the display panel includes a blue light-emitting device B, a green light-emitting device G and a red light-emitting device R, the blue light-emitting device B includes the first co-doped layer 341, the green light-emitting device G includes the fifth co-doped layer 345. In the blue light-emitting device B, the first co-doped layer 341 is located between the electron blocking layer 323 and the light-emitting layer 31, and the first co-doped layer 341 may weaken the energy level potential barrier between interfaces and improve the hole injection capability. In the green light-emitting device G, the fifth co-doped layer 345 is located between the electron blocking layer 323 and the light-emitting layer 31, and the fifth co-doped layer 345 may weaken the energy level potential barrier between interfaces and improve the hole injection capability.

Moreover, in a manufacturing process of the display panel, since the electron blocking layer 323 and the light-emitting layer 31 need to be patterned according to a light-emitting area of the light-emitting device, that is, an FMM mask is adopted in a same evaporation cavity to manufacture a patterned pattern, addition of the co-doped layer 34 between the electron blocking layer 323 and the light-emitting layer 31 does not increase processes and evaporation cavities.

Furthermore, in the display panel provided by an embodiment of the present disclosure, as shown in FIG. 14, the red light-emitting device R further include the seventh co-doped layer 347 located between the electron blocking layer 323 and the light-emitting layer 31, so that the red light-emitting device R keeps the same manufacturing process with the blue light-emitting device B and the green light-emitting device G.

During manufacturing the display panel, the hole injection layers 321 in light-emitting devices of respective colors may be manufactured by adopting an open mask in an evaporation cavity, the hole transport layers 322 in the light-emitting devices of respective colors may be manufactured by adopting an open mask by moving to another evaporation cavity, the electron blocking layer 323, the first co-doped layer 341 and the light-emitting layer 31 in the blue light-emitting device are manufactured by adopting an FMM mask by moving to another evaporation cavity, the electron blocking layer 323, the fifth co-doped layer 345 and the light-emitting layer 31 in the green light-emitting device are manufactured by adopting an FMM mask by moving to another evaporation cavity, the electron blocking layer 323, the seventh co-doped layer 347 and the light-emitting layer 31 in the red light-emitting device are manufactured by adopting an FMM mask by moving to another evaporation cavity, and then the hole blocking layers 331, the electron transport layers 332 and other film layers are manufactured by moving to other evaporation cavities.

Based on the same inventive conception, an embodiment of the present disclosure further provides a display apparatus, including the display panel provided by an embodiment of the present disclosure, and the display apparatus may be a mobile phone, a tablet personal computer, a television, a display, a notebook computer, a digital photo frame, a navigator and other any products or components with display functions. Other essential components of the display apparatus should be understood by those ordinarily skilled in the art, which is not repeated here, nor shall it be taken as a limitation of the present disclosure. The implementation of the display apparatus may refer to an embodiment of the display panel, and the repetition is not repeated.

According to the light-emitting device, the display panel and the display apparatus provided by embodiments of the present disclosure, the co-doped layer is added between interfaces with the difference in the material physical properties being greater than the set value, which may obviously reduce the difference in the physical properties of the adjacent interfaces, enhance the injection capability of the charges, and obviously reduce accumulation of the charges on the interfaces, thereby weakening the difference in the interfaces in the light-emitting device and improving the performance of the device. Compared with the traditional method that an auxiliary function layer is added in a light-emitting device to weaken the difference in the physical properties on interfaces, a new organic material does not need to be introduced, the requirement of the traditional method of adding the auxiliary function layer for the property (such as the energy level) of the newly-introduced organic material is higher, the property (such as the energy level) needs to be located between the properties (such as the energy levels) of two interface materials, and therefore particular material design is needed. In the light-emitting device provided by an embodiment of the present disclosure, materials of adjacent interfaces with greater difference in the physical properties are mutually doped to form the co-doped layer, which ensures that the good contact interface is formed between the co-doped layer and adjacent film layers and injection and transport of the charges are more easily performed.

Obviously, those skilled in the art may make various modifications and variations to the present disclosure without departing from the spirit and scope of the present disclosure. In this way, if these modifications and variations of the present disclosure fall within the scope of the claims of the present disclosure and equivalent technologies thereof, the present disclosure is also intended to include these modifications and variations.

1. A light-emitting device, comprising an anode and a cathode arranged oppositely, and a light-emitting function layer located between the anode and the cathode;
the light-emitting function layer comprising a light-emitting layer, a first auxiliary function layer located between the light-emitting layer and the anode, a second auxiliary function layer located between the light-emitting layer and the cathode, and at least one co-doped layer; and
a difference in material physical properties between two film layers adjacent to the co-doped layer being greater than a set value, and the co-doped layer comprising a material formed by mixing materials of the two adjacent film layers.

2. The light-emitting device according to claim 1, wherein an energy level potential barrier between the two film layers adjacent to the co-doped layer is greater than or equal to 0.2 eV.

3. The light-emitting device according to claim 2, wherein the first auxiliary function layer comprises an electron blocking layer;
the light-emitting layer comprises a blue organic light-emitting material, and an energy level potential barrier between the electron blocking layer and the light-emitting layer is greater than 0.2 eV; and
the co-doped layer comprises a first co-doped layer located between the electron blocking layer and the light-emitting layer;
wherein an HOMO value of the blue organic light-emitting material is 5.9 eV, and an HOMO value of the electron blocking layer is 5.5 eV.

4. (canceled)

5. The light-emitting device according to claim 2, wherein the first auxiliary function layer comprises a hole transport layer;
the light-emitting layer comprises a blue organic light-emitting material, and an energy level potential barrier between the hole transport layer and the light-emitting layer is greater than 0.2 eV; and
the co-doped layer comprises a second co-doped layer located between the hole transport layer and the light-emitting layer;
wherein an HOMO value of the blue organic light-emitting material is 5.9 eV, and an HOMO value of the hole transport layer is 5.4 eV.

6. (canceled)

7. The light-emitting device according to claim 2, wherein the second auxiliary function layer comprises an electron transport layer and a hole blocking layer;
an energy level potential barrier between the electron transport layer and the hole blocking layer is greater than 0.2 eV; and
the co-doped layer comprises a third co-doped layer located between the electron transport layer and the hole blocking layer;
wherein an LUMO value of the electron transport layer is 3.0 eV, and an LUMO value of the hole blocking layer is 2.6 eV.

8. (canceled)

9. The light-emitting device according to claim 2, wherein the second auxiliary function layer comprises a hole blocking layer;
the light-emitting layer comprises a green organic light-emitting material, and an energy level potential barrier between the hole blocking layer and the light-emitting layer is greater than 0.2 eV; and
the co-doped layer comprises a fourth co-doped layer located between the hole blocking layer and the light-emitting layer;
wherein an LUMO value of the hole blocking layer is 2.6 eV, and an LUMO value of the green organic light-emitting material is 2.3 eV.

10. (canceled)

11. The light-emitting device according to claim 1, wherein a difference in a carrier mobility between the two film layers adjacent to the co-doped layer is greater than an order of magnitude.

12. The light-emitting device according to claim 11, wherein the first auxiliary function layer comprises an electron blocking layer;
the light-emitting layer comprises a green organic light-emitting material, and a difference in a hole mobility between the electron blocking layer and the light-emitting layer is at least an order of magnitude; and
the co-doped layer comprises a fifth co-doped layer located between the electron blocking layer and the light-emitting layer;
wherein a hole mobility of the electron blocking layer is 2.2 E-04 cm²/Vs, and a hole mobility of the green organic light-emitting material is 2.8 E-07 cm²/Vs.

13. (canceled)

14. The light-emitting device according to claim 11, wherein the first auxiliary function layer comprises a hole transport layer;
the light-emitting layer comprises a green organic light-emitting material, and a difference in a hole mobility between the hole transport layer and the light-emitting layer is at least an order of magnitude; and
the co-doped layer comprises a sixth co-doped layer located between the hole transport layer and the light-emitting layer.

15. The light-emitting device according to claim 12, wherein a hole mobility of the hole transport layer is 2.2 E-04 cm²/Vs, and a hole mobility of the green organic light-emitting material is 2.8 E-07 cm²/Vs.

16. The light-emitting device according to claim 1, wherein a thickness of the co-doped layer is 3 nm to 10 nm.

17. The light-emitting device according to claim 16, wherein the thickness of the co-doped layer is 5 nm to 8 nm.

18. The light-emitting device according to claim 1, wherein a mass ratio of materials of the two adjacent film layers in the co-doped layer is 1:9 to 9:1.

19. The light-emitting device according to claim 18, wherein the mass ratio of the materials of the two adjacent film layers in the co-doped layer is 1:1.

20. The light-emitting device according to claim 3, wherein a light-emitting host material in the blue organic light-emitting material is TCTA or Bphen, and a guest material in the blue organic light-emitting material is an aromatic or aniline luminophore; and
a material of the hole transport layer is a triphenylamine, butadiene or styryl triphenylamine compound, and a material of the electron blocking layer is an aniline or carbazole compound.

21. The light-emitting device according to claim 7, wherein a material of the hole blocking layer is BCP, and a material of the electron transport layer is PBD or NCB.

22. A display panel, comprising a plurality of light-emitting devices according to claim 1.

23. The display panel according to claim 22, wherein the light-emitting devices comprise a blue light-emitting device, a green light-emitting device and a red light-emitting device; and
the blue light-emitting device comprises a first co-doped layer, and the green light-emitting device comprises a fifth co-doped layer.

24. The display panel according to claim 23, wherein the red light-emitting device comprises a seventh co-doped layer located between an electron blocking layer and the light-emitting layer.

25. A display apparatus, comprising the display panel according to claim 22.
